(19) United States
(12) Patent Application Publication
(10) Pub. No.: US 2016/0378594 A1
(43) Pub. Date: Dec. 29, 2016

(54) METHOD AND APPARATUS TO DECODE LOW DENSITY PARITY CODES

(71) Applicant: Intel Corporation, Santa Clara, CA (US)

(72) Inventor: Ravi H. Motwani, San Diego, CA (US)

(73) Assignee: INTEL CORPORATION, Santa Clara, CA (US)

(21) Appl. No.: 14/752,322

(22) Filed: Jun. 26, 2015

(51) Int. Cl. G06F 11/10; H03M 13/11; G11C 29/52

(52) U.S. Cl. CPC G06F 11/1068; G11C 29/52; H03M 13/1128

(57) ABSTRACT

Apparatus, systems, and methods for recovery algorithm in memory are described. In one embodiment a memory comprises a memory device and a controller coupled to the memory device and comprising logic, at least partially including hardware logic, to in response to a read request received from a host device, retrieve data from the memory device, perform an error correction code (ECC) check on the data retrieved from the memory device, invoke a recovery operation in response to an ECC error, wherein the recovery operation performs a non-binary, iterative symbol flipping procedure. Other embodiments are also disclosed and claimed.

### TECHNICAL FIELD

The present disclosure generally relates to the field of electronics. More particularly, some embodiments of the invention generally relate to decoding of low density parity codes in memory for electronic devices.

### BACKGROUND

In some examples error correction codes (ECC) may be used to protect data stored in non-volatile memory, e.g., flash memory or the like from raw bit errors. Examples of ECC codes may include Bose-Chaudhuri (BCH) codes, Reed-Solomon codes, low-density parity check (LDPC), Convolutional Codes, Hamming Codes, or the like.

Non-Binary LDPC codes exhibit better performance in error correction and recovery than binary LDPC codes. A min-sum decoder exhibits performance levels which come close to maximum likelihood decoding. However, the min-sum decoder consumes significant amounts of power and imposes a high degree of latency in decoding. Bit flipping algorithms (BFA) are generally used to decode binary LDPC codes. However, bit flipping algorithms generally exhibit poor performance.

There is a shortage in the art of high-performing symbol-flipping algorithms for non-binary LDPC codes. Accordingly, techniques to improve symbol-flipping algorithms for non-binary LDPC codes may find utility, e.g., in memory systems for electronic devices.

### BRIEF DESCRIPTION OF THE DRAWINGS

The detailed description is provided with reference to the accompanying figures. The use of the same reference numbers in different figures indicates similar or identical items.

FIG. 1 is a schematic, block diagram illustration of components of apparatus to implement an operation to decode low density parity codes in non-volatile memory in accordance with various examples discussed herein.

FIG. 2 is a schematic, block diagram illustration of a memory architecture to implement an algorithm to decode low density parity codes in write operations in non-volatile memory in accordance with various examples discussed herein.

FIG. 3 is a schematic illustration of voltage characteristics of a multi-level memory device in which a method to implement an algorithm to decode low density parity codes in read operations in non-volatile memory may be implemented in accordance with various embodiments discussed herein.

FIGS. 4-5 are flowcharts illustrating operations in a method to implement an algorithm to decode low density parity codes in read operations in non-volatile memory accordance with various embodiments discussed herein.

FIGS. 6-10 are schematic, block diagram illustrations of electronic devices which may be adapted to implement memory recovery management in accordance with various embodiments discussed herein.

### DESCRIPTION OF EMBODIMENTS

In the following description, numerous specific details are set forth in order to provide a thorough understanding of various embodiments. However, various embodiments of the invention may be practiced without the specific details. In other instances, well known methods, procedures, components, and circuits have not been described in detail so as not to obscure the particular embodiments of the invention. Further, various aspects of embodiments of the invention may be performed using various means, such as integrated semiconductor circuits (“hardware”), computer readable instructions organized into one or more programs (“software”), or some combination of hardware and software. For the purposes of this disclosure reference to “logic” shall mean either hardware, software, or some combination thereof.

By way of background, a non-binary LDPC code is a code for which a parity check matrix H has entries which are not restricted to binary values (0 and 1), but may include elements from a Galois Field GF(q) field. The integer q can take values greater than 2. A sample H matrix for GF(3) can be:

$$\begin{matrix}1 & 1 & 1 & 0 & 0 & 0 \\ 2 & 0 & 0 & 2 & 0 & 0 \\ 0 & 0 & 2 & 0 & 0 & 1\end{matrix}$$

The parity check operations which are the rows of the H matrix have multiplication between elements of GF(3) and additions of GF(3) elements. For example, the second row of the parity check matrix means

2C₀+2C₃=0 EQ 1

where the multiplication is a GF(3) multiplication and the addition is in GF(3). The Cn variable is how symbols in a received string being tested as a codeword are denoted. So a 6-symbol LDPC code would have C0,C1C2,C3,C4,C5. The received symbols are tested against the parity check equations and if they produce all zeros then the codeword is deemed valid. If not, then the codeword is not valid. For example, C0 and C3 are symbols in a codeword. C0 is the first symbol in the codeword and c3 is the fourth symbol in the codeword.

In some examples a non-binary LDPC code may be decoded using a min-sum decoder, which generates extrinsic information based on each check operation. For example the first check operation generates extrinsic information about C₀ given by the operation:

p(c₀=1)=p(c₁=0)p(c₂=0)+p(c₁=1)+p(c₂=2)+p(c₁=2)p(c₂=1) EQ 2

As described above, symbol flipping algorithms may be useful to decode non-binary LDPC codes. Described herein are examples of bit flipping algorithms to decode non-binary LDPC codes. The bit flipping algorithms described herein may be embodied as logic, at least partially including hardware logic, embedded in a memory controller, which in turn may be used within a memory system in a electronic device, e.g. a computing device, a mobile phone, an electronic reader, or other electronic device.

In operation, a memory controller in an electronic device may receive a read request from a host device, e.g., a system level memory controller or the like, to read data stored on a memory device coupled to the memory controller. In response to the read request, the memory controller may retrieve data from the memory device, perform an error correction code (ECC) check on the data retrieved from the memory device, and return the data to the host device when the ECC check indicates that the data retrieved from the memory device is free of errors. By contrast, the controller invokes a recovery algorithm in response to an error in the ECC check on the data retrieved from the memory device.

In the event that an error in the ECC check cannot be resolved, the controller may implement a recovery algorithm which uses symbols from one or more codewords associated with the data. In some examples the controller may implement a bit-flipping algorithm which attempts to make informed choices regarding which symbols in the codeword to flip. In one example it selects a symbol from the plurality of symbols which results in one or more non-zero parity check operations, determines a first number which represents a number of parity check operations which indicate that the symbol should be decreased, and determines a second number which represents a number of parity check operations which indicate that the symbol should be increased. The controller may then decrease the symbol when the first number is greater than the second number or increase the symbol when the first number is greater than the second number, or assign a low confidence rating to the symbol when the first number is equal to the second number. Ultimately the controller may return a read error to the host device when one or more of the parity check operations includes a 1 after iterative symbol flipping procedure terminates. This example is for the GF(3)case. For a general GF(q) case, some operations may say that the symbol has value x, some may say it have value y, eventually, a value based on a majority vote.

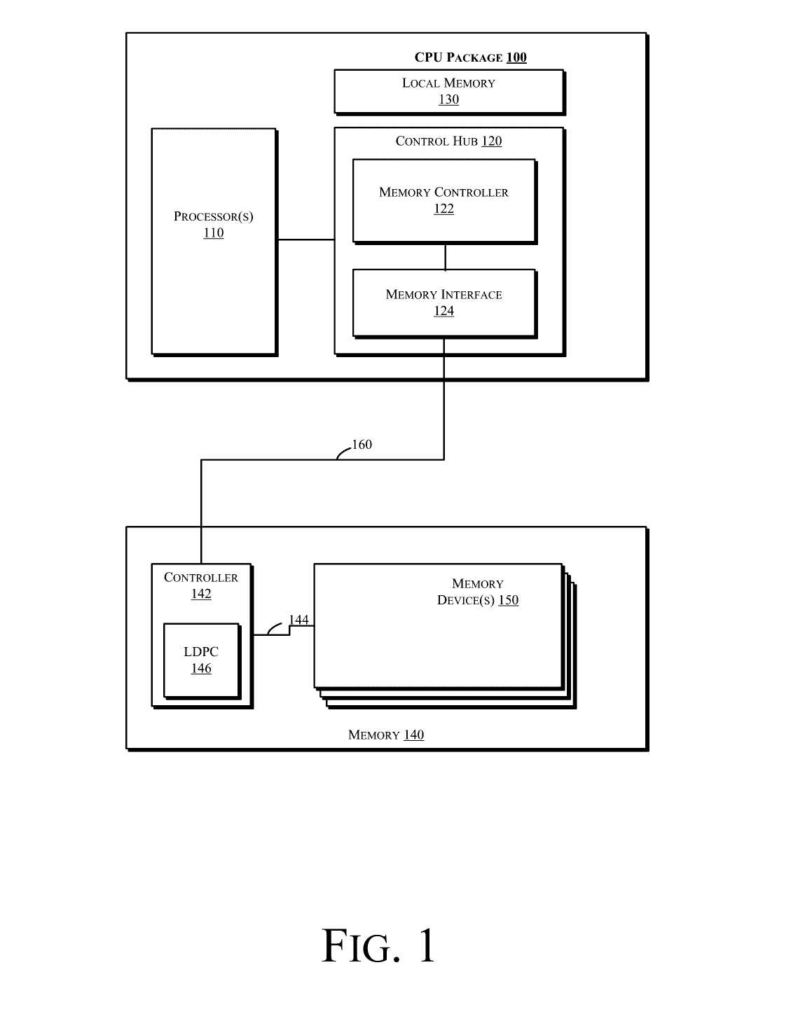

FIG. 1 is a schematic, block diagram illustration of components of apparatus to implement an algorithm to decode low density parity codes in memory in accordance with various examples discussed herein. Referring to FIG. 1, in some embodiments a central processing unit (CPU) package 100 which may comprise one or more processors 110 coupled to a control hub 120 and a local memory 130. Control hub 120 comprises a memory controller 122 and a memory interface 124.

Memory interface 124 is coupled to a remote memory 140 by a communication bus 160. In some examples, the communication bus 160 may be implemented as traces on a printed circuit board, a cable with copper wires, a fibre optic cable, a connecting socket, or a combination of the above. Memory 140 may comprise a controller 142 and one or more memory device(s) 150. In various embodiments, at least some of the memory devices 150 may be implemented using volatile memory, e.g., static random access memory (SRAM), a dynamic random access memory (DRAM), or non-volatile memory, e.g., phase change memory, NAND (flash) memory, ferroelectric random-access memory (FeRAM), nanowire-based non-volatile memory, memory that incorporates memristor technology, three dimensional (3D) cross point memory such as phase change memory (PCM), spin-transfer torque memory (STT-RAM), magnetoresistive random access memory (MRAM), or NAND flash memory. The specific configuration of the memory device(s) 150 in the memory 140 is not critical.

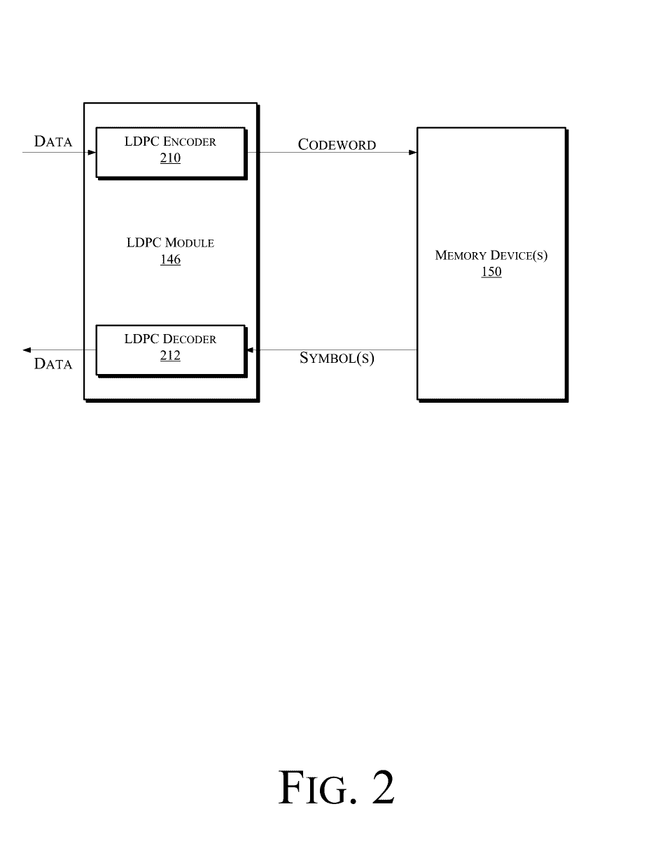

In some examples controller 142 may comprise, or be communicatively coupled to, an LDPC module 146 to encode and decode soft data (i.e., symbols from a codword) for ECC purposes. FIG. 2 is a schematic, block diagram illustration of a memory architecture to implement an algorithm to decode low density parity codes in write operations in non-volatile memory in accordance with various examples discussed herein. Referring to FIG. 2, in some examples user data is input to an LDPC encoder 210 which encodes the user data into an LDPC codeword, which may be either a binary LDPC codeword or a non-binary LDPC codeword. A non-binary LDPC codeword may include non-binary symbols corresponding to any of the elements in Galois Field (q) (denoted GF(q)), where q represents the number of elements in the Galois field.

The codeword may be stored in the memory device(s) 150. In examples in which data is stored across multiple dies in the memory devices 150 in memory 140, the codeword may similarly be stored across multiple dies. The particular number of dies in the memory is not critical.

During a recovery process the codeword may be retrieved from the memory devices as a plurality of symbols. The symbols may be input to a LDPC decoder 212 which decodes the symbols of the codeword and which may be used to correct errors in the codeword.

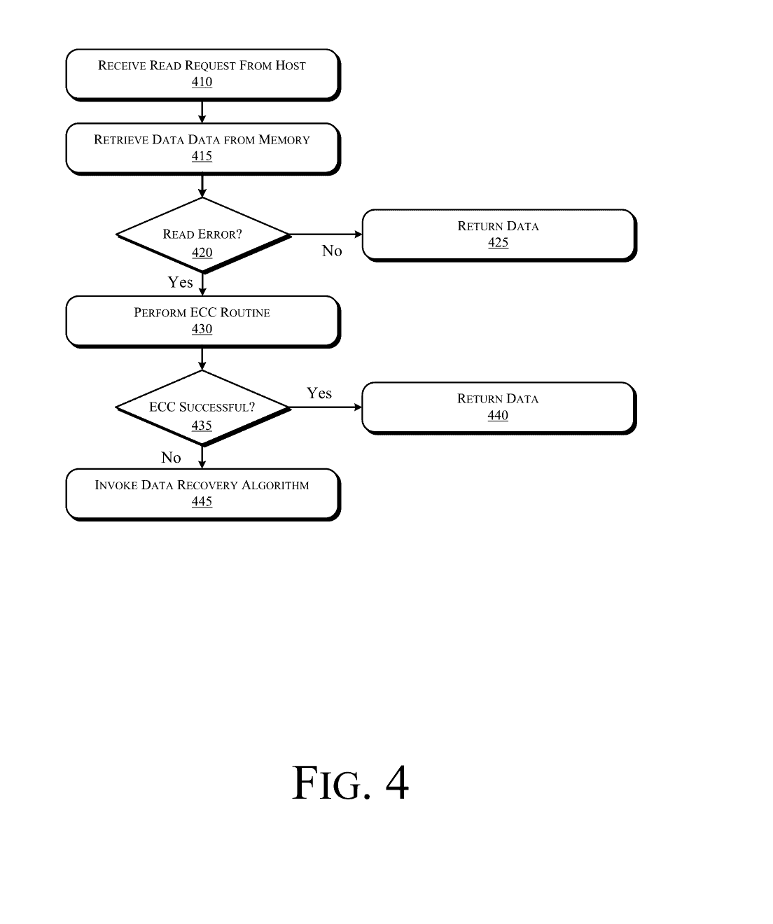

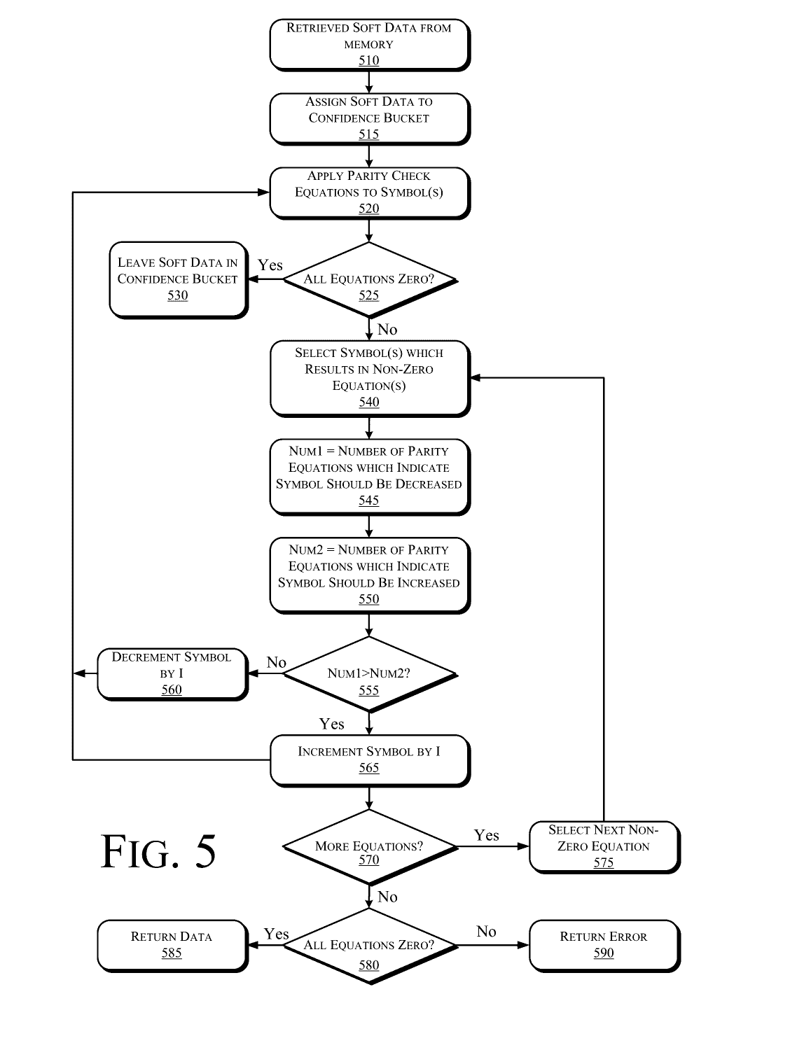

Examples of a symbol flipping algorithm will be described with reference to FIGS. 4 and 5, and with reference to a multi-level NAND memory device. FIG. 4 depicts operations in a first aspect of a method to implement an algorithm to decode low density parity codes in memory. In some examples the operations depicted in FIG. 4 may be implemented by logic in the controller 142, alone or in combination with logic in the memory controller 122 in the CPU package 100. Referring now to FIG. 4, at operation 410 the controller 142 receives a read request form a host device, e.g., from memory controller 122. The read request may include a logical address for a block of data stored in memory device(s) 150. Controller 142 may translate the logical address received with the read request to a physical address in memory device(s) 150.

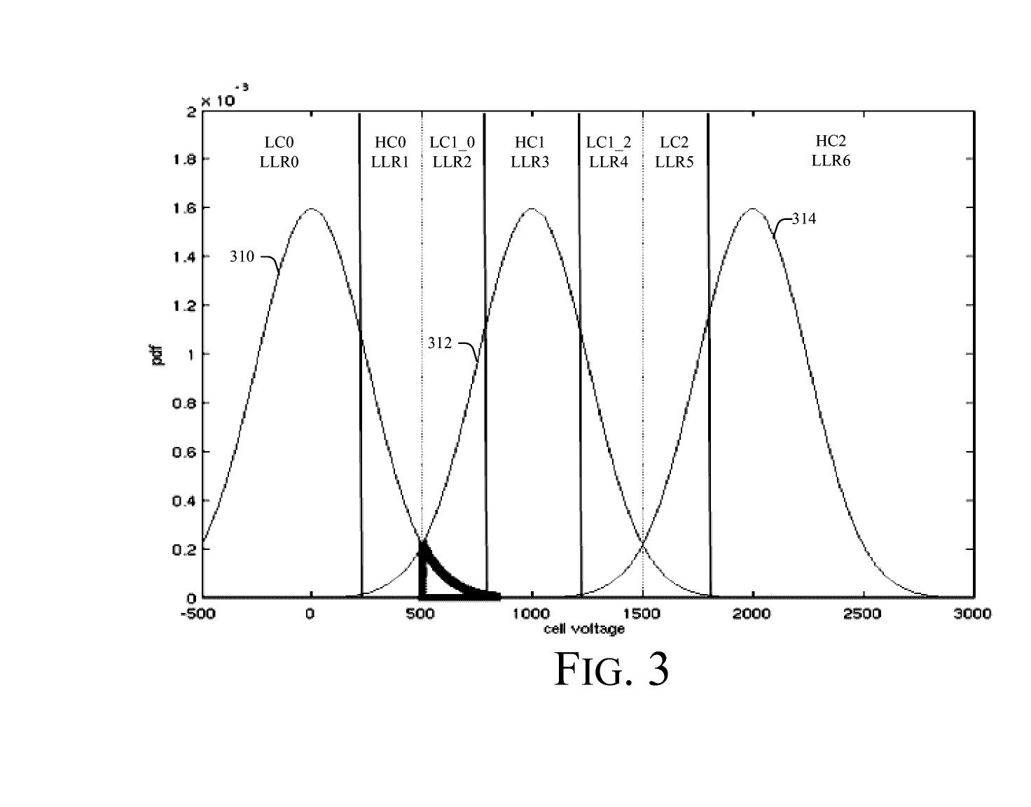

At operation 415 the controller 141 may retrieve the data from memory. FIG. 3 is a schematic illustration of voltage characteristics of a multi-level memory device in which a method to implement an algorithm to decode low density parity codes in read operations in non-volatile memory may be implemented in accordance with various embodiments discussed herein. Referring to FIG. 3, in some examples a three-level memory cell may be characterized by three voltage response curves, 310, 312, 314, one for each memory location in the cell. In use, during a read operation the controller 142 may apply a series of at least two voltages, commonly referred to as reference voltages, to the memory cell which corresponds to the physical address in the read request.

If, at operation 420, the data retrieved is devoid of errors then control passes to operation 425 and the controller 142 returns the data retrieved from memory. By contrast, if at operation 420 there is a read error then control passes to operation 430 and the controller 142 implements an ECC algorithm to try to correct the read error.

If, at operation 435, the ECC routine is successful in correcting the read error then control passes to operation 440 and the controller 142 returns the data retrieved from memory. By contrast, if at operation 435 the ECC routine was unsuccessful in correcting the read error then control passes to operation 445 and the controller 142 implements a data recovery algorithm which includes an algorithm to decode low density parity codes.

One example of an algorithm to decode low density parity codes will be described with reference to FIG. 5. Referring to FIG. 5, at operation 510 the soft data (i.e., the ECC codeword) associated with the data requested in the read operation is retrieved from the memory devices 150. Referring briefly to FIG. 3, in one example, the controller 142 applies a series of six voltage strobes to the memory device to retrieve soft information in log-likelihood ratio (LLR) format about the reliabilities for the three voltage levels in the cell. At operation 515 the soft data retrieved is assigned into confidence buckets. Referring to FIG. 3, the six voltage strobes define seven buckets which are assigned LLR values as follows:

TABLE I

| Voltage Range | Value | Bucket | LLR Value |
|---|---|---|---|
| 0-350 | Low Confidence 0 | LC0 | 0 |
| 350-500 | High Confidence 0 | HC0 | 1 |
| 500-750 | Low Confidence 1_0 | LC1_0 | 2 |
| 750-1250 | High Confidence 0 | HC1 | 3 |
| 1250-1500 | Low Confidence 1_2 | LC1_2 | 4 |
| 1500-1750 | Low Confidence 2 | LC2 | 5 |
| 1750-3000 | High Confidence 2 | HC2 | 6 |

At operation 520 the controller applies a parity check operation(s) derived from the H matrix for the non-binary LDPC code to a first symbol or set of symbols in the codeword retrieved from the memory. If, at operation 525, the result of parity check operations on the symbol(s) are zero then control passes to operation 530 and the symbols are left in their confidence bucket. By contrast, if at operation 525 the result of one or more of the parity check operations on the symbols are not zero then control passes to operation 540 and one or more symbols which result in non-zero parity check operations are selected.

By way of example, if applying the parity check operation (EQ 1) above to the symbols, which is 2C₀+2C₃=0, where C0 and C3 represented symbols 0 and 3 in the codeword, results in a value of 1 instead of 0, then symbols 0 and 3 of the codeword will be flagged as potential symbols of the codeword to flip. Whether to flip a specific symbol depends on the number of parity check operations which result in non-zero values. Thus, at operation 545, for each symbol in the codeword a parameter NUM1 is set to correspond to the number of parity check operations which indicate that the symbol should be decreased by a value of 1 (i.e., the number of parity check operations which result in a “0” if the symbol is decreased by a value of 1). Similarly, at operation 550 for each symbol in the codeword a parameter NUM2 is set to the number of parity check operations which indicate that the symbol should be increased by a value of 1 (i.e., the number of parity check operations which result in a “0” if the symbol is increased by a value of 1). When a parity check equation fails (i.e., results in a “1”) for a given Cn, all other parity check equations for the given Cn are evaluated to determine whether they result in a “0” or a “1”. If they result in a “1” then the count (NUM1 or Num2) is increased. If they result in a zero, then the counts are not increased. Thus, for parity check operation (EQ 1), since 2C₀+2C₃=1, the remaining parity check operation for C₀(C₀=1/2=2) must also be considered.

If, at operation 555 the parameter NUM1 is less than the parameter NUM2 then control passes to operation 560 and the symbol is decremented by 1. By contrast, if at operation 555 the parameter NUM1 is greater than the parameter NUM2 then control passes to operation 565 and the symbol is incremented by 1. In either case the confidence level associated with the symbol is changed to low confidence. In the event that NUM1=NUM2 the symbol is left unchanged but the confidence level associated with the symbol is changed to low confidence.

If, at operation 570, there are more parity check operations to be tested then control passes to operation 575 and the next non-zero parity check operation is selected. Control then passes back to operation 545 and the parameters NUM1 and NUM 2 are generated for the symbols in the non-zero parity check operation. Thus, operations 545-575 define a loop pursuant to which the symbols in non-zero parity check operations are systematically tested using the values NUM1 and NUM2 in operations 545-550 to determine which symbols are more likely to generate an error-free set of parity check operations if they are flipped. By contrast, if at operation 570 there are no more parity check operations to be evaluated then control passes to operation 580.

If, at operation 580 all parity check operations are zero then the recovery routine has converged and the data can be returned to the requesting entity (operation 585). By contrast, if, at operation 580 not all parity check operations are zero then the recovery routine has failed to converge and an error can be returned to the requesting entity (operation 590).

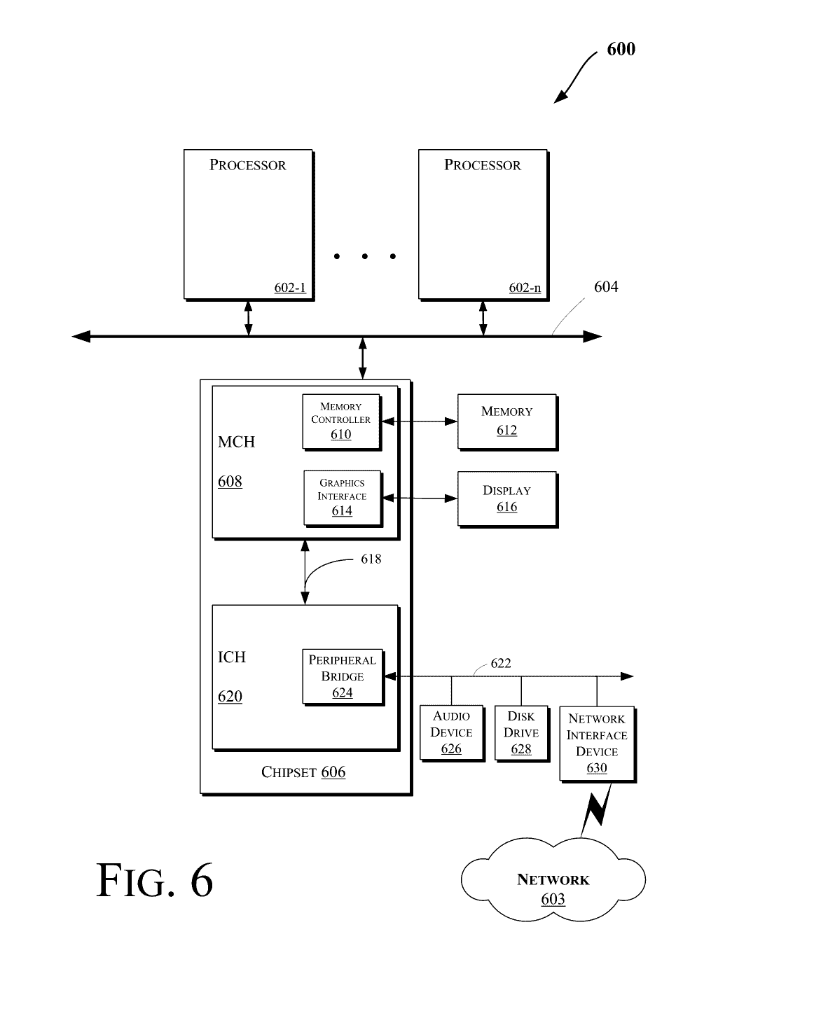

As described above, in some embodiments the electronic device may be embodied as a computer system. FIG. 6 illustrates a block diagram of a computing system 600 in accordance with an embodiment of the invention. The computing system 600 may include one or more central processing unit(s) (CPUs) 602 or processors that communicate via an interconnection network (or bus) 604. The processors 602 may include a general purpose processor, a network processor (that processes data communicated over a computer network 603), or other types of a processor (including a reduced instruction set computer (RISC) processor or a complex instruction set computer (CISC)). Moreover, the processors 602 may have a single or multiple core design. The processors 602 with a multiple core design may integrate different types of processor cores on the same integrated circuit (IC) die. Also, the processors 602 with a multiple core design may be implemented as symmetrical or asymmetrical multiprocessors. In an embodiment, one or more of the processors 602 may be the same or similar to the processors 102 of FIG. 1. For example, one or more of the processors 602 may include the control unit 120 discussed with reference to FIGS. 1-3. Also, the operations discussed with reference to FIGS. 3-5 may be performed by one or more components of the system 600.

A chipset 606 may also communicate with the interconnection network 604. The chipset 606 may include a memory control hub (MCH) 608. The MCH 608 may include a memory controller 610 that communicates with a memory 612 (which may be the same or similar to the memory 130 of FIG. 1). The memory 412 may store data, including sequences of instructions, that may be executed by the CPU 602, or any other device included in the computing system 600. In one embodiment of the invention, the memory 612 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk or a solid state drive (SSD). Additional devices may communicate via the interconnection network 604, such as multiple CPUs and/or multiple system memories.

The MCH 608 may also include a graphics interface 614 that communicates with a display device 616. In one embodiment of the invention, the graphics interface 614 may communicate with the display device 616 via an accelerated graphics port (AGP). In an embodiment of the invention, the display 616 (such as a flat panel display) may communicate with the graphics interface 614 through, for example, a signal converter that translates a digital representation of an image stored in a storage device such as video memory or system memory into display signals that are interpreted and displayed by the display 616. The display signals produced by the display device may pass through various control devices before being interpreted by and subsequently displayed on the display 616.

A hub interface 618 may allow the MCH 608 and an input/output control hub (ICH) 620 to communicate. The ICH 620 may provide an interface to I/O device(s) that communicate with the computing system 600. The ICH 620 may communicate with a bus 622 through a peripheral bridge (or controller) 624, such as a peripheral component interconnect (PCI) bridge, a universal serial bus (USB) controller, or other types of peripheral bridges or controllers. The bridge 624 may provide a data path between the CPU 602 and peripheral devices. Other types of topologies may be utilized. Also, multiple buses may communicate with the ICH 620, e.g., through multiple bridges or controllers. Moreover, other peripherals in communication with the ICH 620 may include, in various embodiments of the invention, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 622 may communicate with an audio device 626, one or more disk drive(s) 628, and a network interface device 630 (which is in communication with the computer network 603). Other devices may communicate via the bus 622. Also, various components (such as the network interface device 630) may communicate with the MCH 608 in some embodiments of the invention. In addition, the processor 602 and one or more other components discussed herein may be combined to form a single chip (e.g., to provide a System on Chip (SOC)). Furthermore, the graphics accelerator 616 may be included within the MCH 608 in other embodiments of the invention.

Furthermore, the computing system 600 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 628), a floppy disk, a compact disk ROM (CD-ROM), a digital versatile disk (DVD), flash memory, a magneto-optical disk, or other types of nonvolatile machine-readable media that are capable of storing electronic data (e.g., including instructions).

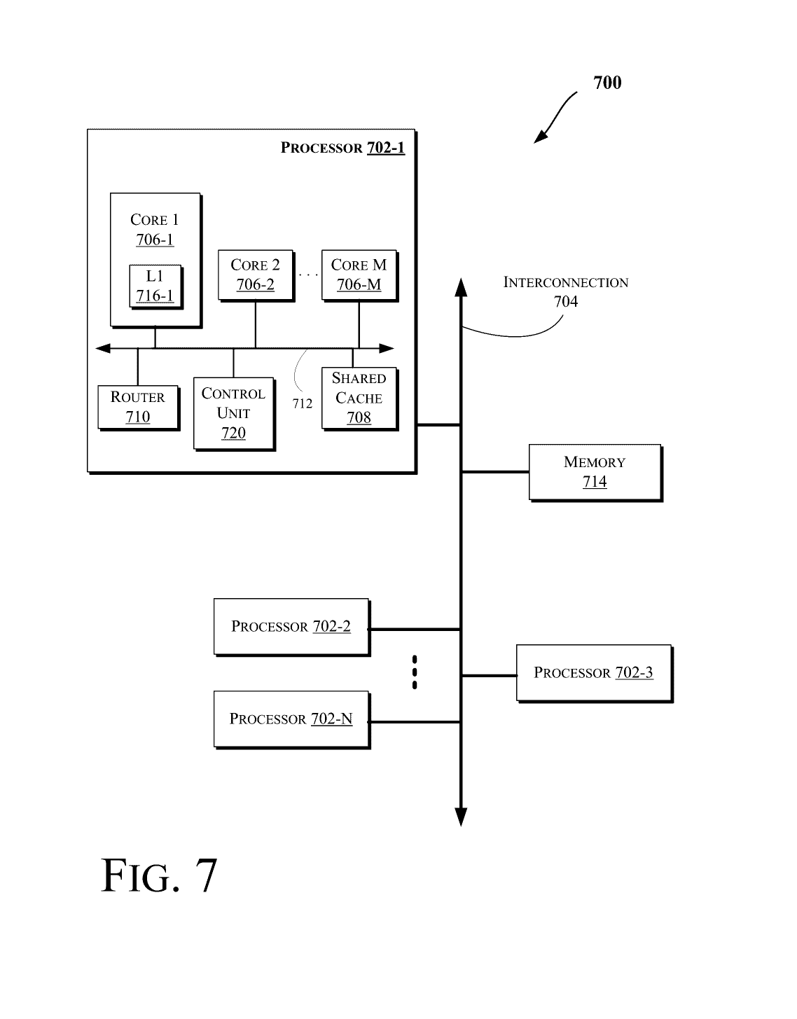

FIG. 7 illustrates a block diagram of a computing system 700, according to an embodiment of the invention. The system 700 may include one or more processors 702-1 through 702-N (generally referred to herein as “processors 702” or “processor 702”). The processors 702 may communicate via an interconnection network or bus 704. Each processor may include various components some of which are only discussed with reference to processor 702-1 for clarity. Accordingly, each of the remaining processors 702-2 through 702-N may include the same or similar components discussed with reference to the processor 702-1.

In an embodiment, the processor 702-1 may include one or more processor cores 706-1 through 706-M (referred to herein as “cores 706” or more generally as “core 706”), a shared cache 708, a router 710, and/or a processor control logic or unit 720. The processor cores 706 may be implemented on a single integrated circuit (IC) chip. Moreover, the chip may include one or more shared and/or private caches (such as cache 708), buses or interconnections (such as a bus or interconnection network 712), memory controllers, or other components.

In one embodiment, the router 710 may be used to communicate between various components of the processor 702-1 and/or system 700. Moreover, the processor 702-1 may include more than one router 710. Furthermore, the multitude of routers 710 may be in communication to enable data routing between various components inside or outside of the processor 702-1.

The shared cache 708 may store data (e.g., including instructions) that are utilized by one or more components of the processor 702-1, such as the cores 706. For example, the shared cache 708 may locally cache data stored in a memory 714 for faster access by components of the processor 702. In an embodiment, the cache 708 may include a mid-level cache (such as a level 2 (L2), a level 3 (L3), a level 4 (L4), or other levels of cache), a last level cache (LLC), and/or combinations thereof. Moreover, various components of the processor 702-1 may communicate with the shared cache 708 directly, through a bus (e.g., the bus 712), and/or a memory controller or hub. As shown in FIG. 7, in some embodiments, one or more of the cores 706 may include a level 1 (L1) cache 716-1 (generally referred to herein as “L1 cache 716”).

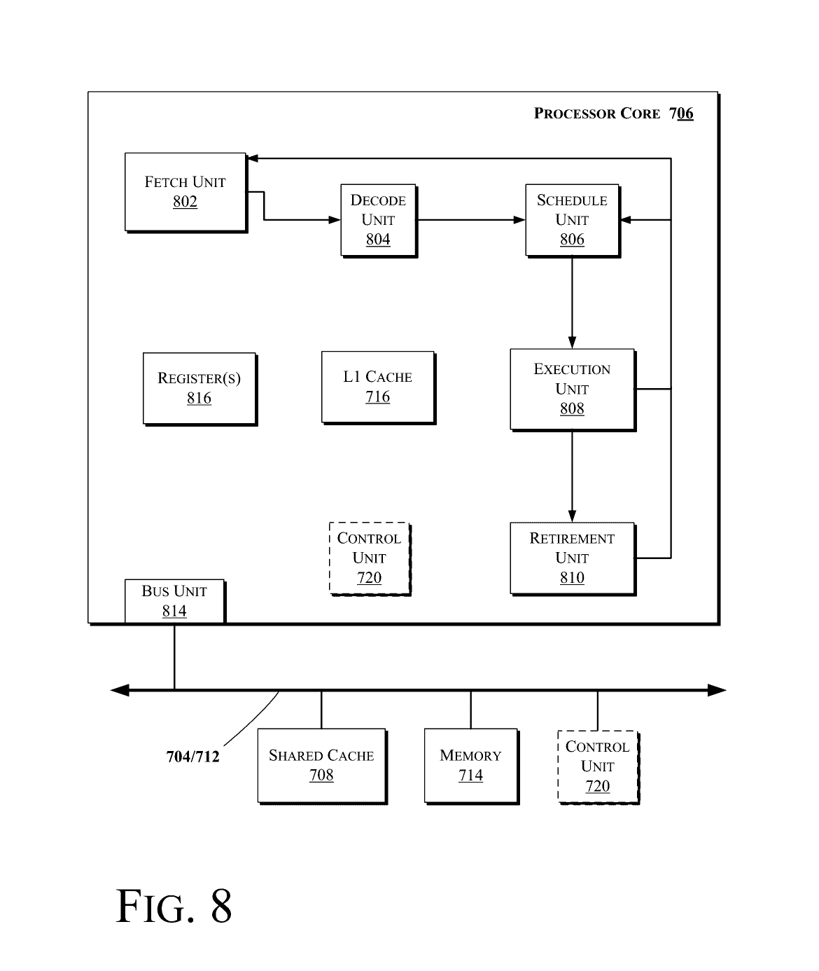

FIG. 8 illustrates a block diagram of portions of a processor core 706 and other components of a computing system, according to an embodiment of the invention. In one embodiment, the arrows shown in FIG. 8 illustrate the flow direction of instructions through the core 706. One or more processor cores (such as the processor core 706) may be implemented on a single integrated circuit chip (or die) such as discussed with reference to FIG. 7. Moreover, the chip may include one or more shared and/or private caches (e.g., cache 708 of FIG. 7), interconnections (e.g., interconnections 704 and/or 112 of FIG. 7), control units, memory controllers, or other components.

As illustrated in FIG. 8, the processor core 706 may include a fetch unit 802 to fetch instructions (including instructions with conditional branches) for execution by the core 706. The instructions may be fetched from any storage devices such as the memory 714. The core 706 may also include a decode unit 804 to decode the fetched instruction. For instance, the decode unit 804 may decode the fetched instruction into a plurality of uops (micro-operations).

Additionally, the core 706 may include a schedule unit 806. The schedule unit 806 may perform various operations associated with storing decoded instructions (e.g., received from the decode unit 804) until the instructions are ready for dispatch, e.g., until all source values of a decoded instruction become available. In one embodiment, the schedule unit 806 may schedule and/or issue (or dispatch) decoded instructions to an execution unit 808 for execution. The execution unit 808 may execute the dispatched instructions after they are decoded (e.g., by the decode unit 804) and dispatched (e.g., by the schedule unit 806). In an embodiment, the execution unit 808 may include more than one execution unit. The execution unit 808 may also perform various arithmetic operations such as addition, subtraction, multiplication, and/or division, and may include one or more an arithmetic logic units (ALUs). In an embodiment, a co-processor (not shown) may perform various arithmetic operations in conjunction with the execution unit 808.

Further, the execution unit 808 may execute instructions out-of-order. Hence, the processor core 706 may be an out-of-order processor core in one embodiment. The core 706 may also include a retirement unit 810. The retirement unit 810 may retire executed instructions after they are committed. In an embodiment, retirement of the executed instructions may result in processor state being committed from the execution of the instructions, physical registers used by the instructions being de-allocated, etc.

The core 706 may also include a bus unit 714 to enable communication between components of the processor core 706 and other components (such as the components discussed with reference to FIG. 8) via one or more buses (e.g., buses 804 and/or 812). The core 706 may also include one or more registers 816 to store data accessed by various components of the core 706 (such as values related to power consumption state settings).

Furthermore, even though FIG. 7 illustrates the control unit 720 to be coupled to the core 706 via interconnect 812, in various embodiments the control unit 720 may be located elsewhere such as inside the core 706, coupled to the core via bus 704, etc.

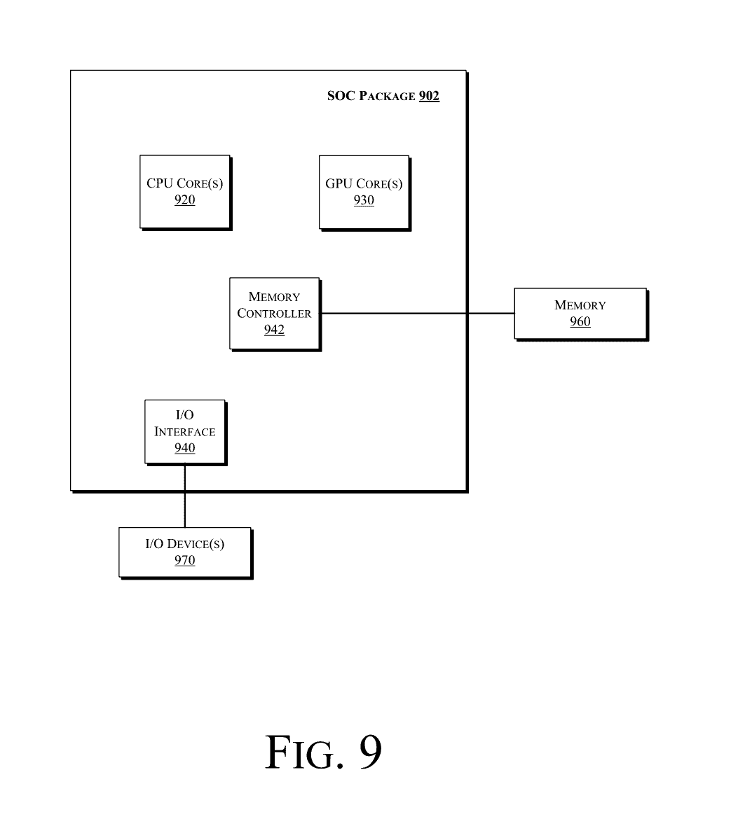

In some embodiments, one or more of the components discussed herein can be embodied as a System On Chip (SOC) device. FIG. 9 illustrates a block diagram of an SOC package in accordance with an embodiment. As illustrated in FIG. 9, SOC 902 includes one or more Central Processing Unit (CPU) cores 920, one or more Graphics Processor Unit (GPU) cores 930, an Input/Output (I/O) interface 940, and a memory controller 942. Various components of the SOC package 902 may be coupled to an interconnect or bus such as discussed herein with reference to the other figures. Also, the SOC package 902 may include more or less components, such as those discussed herein with reference to the other figures. Further, each component of the SOC package 902 may include one or more other components, e.g., as discussed with reference to the other figures herein. In one embodiment, SOC package 902 (and its components) is provided on one or more Integrated Circuit (IC) die, e.g., which are packaged into a single semiconductor device.

As illustrated in FIG. 9, SOC package 902 is coupled to a memory 960 (which may be similar to or the same as memory discussed herein with reference to the other figures) via the memory controller 942. In an embodiment, the memory 960 (or a portion of it) can be integrated on the SOC package 902.

The I/O interface 940 may be coupled to one or more I/O devices 970, e.g., via an interconnect and/or bus such as discussed herein with reference to other figures. I/O device(s) 970 may include one or more of a keyboard, a mouse, a touchpad, a display, an image/video capture device (such as a camera or camcorder/video recorder), a touch screen, a speaker, or the like.

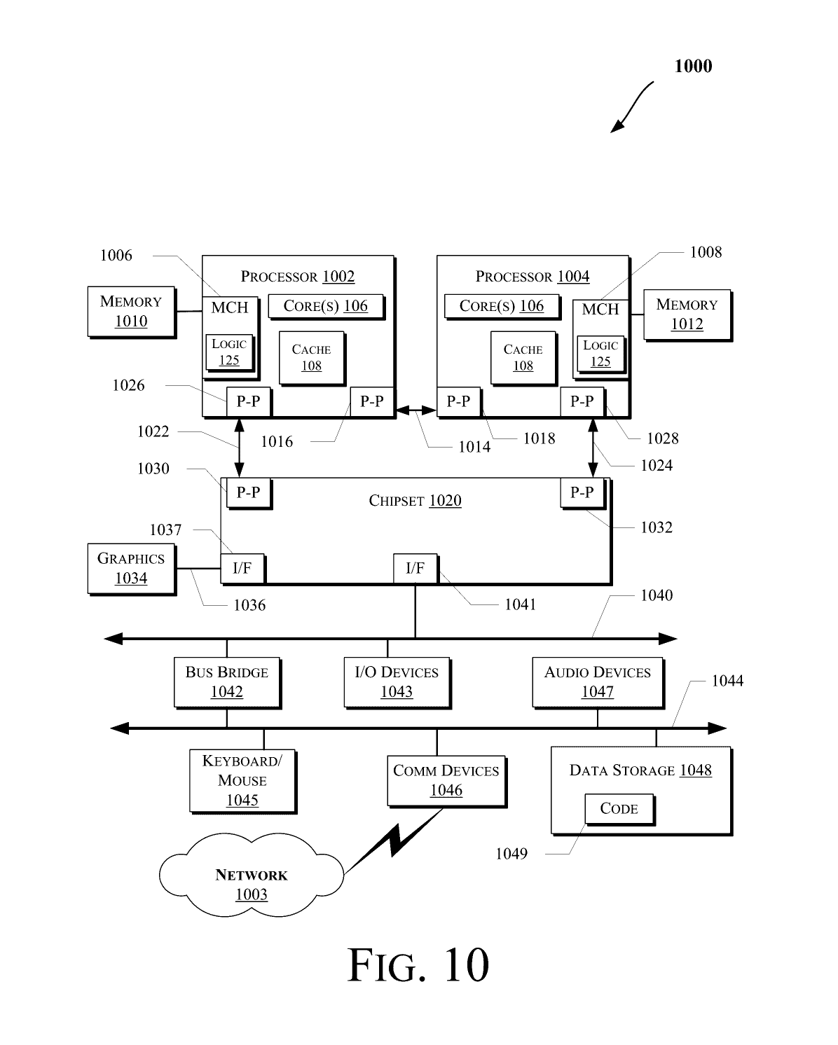

FIG. 10 illustrates a computing system 1000 that is arranged in a point-to-point (PtP) configuration, according to an embodiment of the invention. In particular, FIG. 10 shows a system where processors, memory, and input/output devices are interconnected by a number of point-to-point interfaces.

As illustrated in FIG. 10, the system 1000 may include several processors, of which only two, processors 1002 and 1004 are shown for clarity. The processors 1002 and 1004 may each include a local memory controller hub (MCH) 1006 and 1008 to enable communication with memories 1010 and 1012. MCH 1006 and 1008 may include the memory controller 120 and/or logic 125 of FIG. 1 in some embodiments.

In an embodiment, the processors 1002 and 1004 may be one of the processors 702 discussed with reference to FIG. 7. The processors 1002 and 1004 may exchange data via a point-to-point (PtP) interface 1014 using PtP interface circuits 1016 and 1018, respectively. Also, the processors 1002 and 1004 may each exchange data with a chipset 1020 via individual PtP interfaces 1022 and 1024 using point-to-point interface circuits 1026, 1028, 1030, and 1032. The chipset 1020 may further exchange data with a high-performance graphics circuit 1034 via a high-performance graphics interface 1036, e.g., using a PtP interface circuit 1037.

As shown in FIG. 10, one or more of the cores 106 and/or cache 108 of FIG. 1 may be located within the processors 902 and 904. Other embodiments of the invention, however, may exist in other circuits, logic units, or devices within the system 900 of FIG. 9. Furthermore, other embodiments of the invention may be distributed throughout several circuits, logic units, or devices illustrated in FIG. 9.

The chipset 920 may communicate with a bus 940 using a PtP interface circuit 941. The bus 940 may have one or more devices that communicate with it, such as a bus bridge 942 and I/O devices 943. Via a bus 944, the bus bridge 943 may communicate with other devices such as a keyboard/mouse 945, communication devices 946 (such as modems, network interface devices, or other communication devices that may communicate with the computer network 803), audio I/O device, and/or a data storage device 948. The data storage device 948 (which may be a hard disk drive or a NAND flash based solid state drive) may store code 949 that may be executed by the processors 902 and/or 904.

The Following Pertain to Further Embodiments.

Example 1 is an apparatus, comprising a controller coupled to a memory device and comprising logic, at least partially including hardware logic, to in response to a read request received from a host device, retrieve data from the memory device perform an error correction code (ECC) check on the data retrieved from the memory device invoke a recovery operation in response to an ECC error, wherein the recovery operation performs a non-binary, iterative symbol flipping procedure.

In Example 2, the subject matter of Example 1 can optionally include an arrangement in which the recovery operation retrieves soft data associated with the data associated with the read request, the soft data comprises an ECC codeword comprising a plurality of symbols, and the recovery operation comprises evaluating a result of a plurality of parity check operations performed on the data using the plurality of symbols from the ECC codeword.

In Example 3, the subject matter of any one of Examples 1-2 can optionally include logic, at least partially including hardware logic, to select a symbol from the plurality of symbols which results in one or more non-zero parity check operations, determine a first number which represents a number of parity check operations which indicate that the symbol should be decreased, and determine a second number which represents a number of parity check operations which indicate that the symbol should be increased.

In Example 4, the subject matter of any one of Examples 1-3 can optionally include logic, at least partially including hardware logic, to decrease the symbol when the first number is greater than the second number, and assign a low confidence rating to the symbol.

In Example 5, the subject matter of any one of Examples 1-4 can optionally include logic, at least partially including hardware logic, to successively increase the symbol when the first number is greater than the second number, and assign a low confidence rating to the symbol.

In Example 6, the subject matter of any one of Examples 1-5 can optionally include logic, at least partially including hardware logic, to assign a low confidence rating to the symbol when the first number is equal to the second number.

In Example 7, the subject matter of any one of Examples 1-6 can optionally include logic, at least partially including hardware logic, to return a read error to the host device when one or more of the parity check operations includes a 1 after iterative symbol flipping procedure terminates.

Example 8 is an electronic device comprising a processor and memory, comprising a memory device, and a controller coupled to the memory device and comprising logic, at least partially including hardware logic, to in response to a read request received from a host device, retrieve data from the memory device, perform an error correction code (ECC) check on the data retrieved from the memory device, invoke a recovery operation in response to an ECC error, wherein the recovery operation performs a non-binary, iterative symbol flipping procedure.

In Example 9, the subject matter of Example 8 can optionally include an arrangement in which the recovery operation retrieves soft data associated with the data associated with the read request, the soft data comprises an ECC codeword comprising a plurality of symbols, and the recovery operation comprises evaluating a result of a plurality of parity check operations performed on the data using the plurality of symbols from the ECC codeword.

In Example 10, the subject matter of any one of Examples 8-9 can optionally include logic, at least partially including hardware logic, to select a symbol from the plurality of symbols which results in one or more non-zero parity check operations, determine a first number which represents a number of parity check operations which indicate that the symbol should be decreased, and determine a second number which represents a number of parity check operations which indicate that the symbol should be increased.

In Example 11, the subject matter of any one of Examples 8-10 can optionally include logic, at least partially including hardware logic, to decrease the symbol when the first number is greater than the second number, and assign a low confidence rating to the symbol.

In Example 12, the subject matter of any one of Examples 8-11 can optionally include logic, at least partially including hardware logic, to successively increase the symbol when the first number is greater than the second number, and assign a low confidence rating to the symbol.

In Example 13, the subject matter of any one of Examples 8-12 can optionally include logic, at least partially including hardware logic, to assign a low confidence rating to the symbol when the first number is equal to the second number.

In Example 14, the subject matter of any one of Examples 8-13 can optionally include logic, at least partially including hardware logic, to return a read error to the host device when one or more of the parity check operations includes a 1 after iterative symbol flipping procedure terminates.

Example 15 is a controller comprising logic, at least partially including hardware logic, which, when executed, configures the controller to in response to a read request received from a host device, retrieve data from the memory device, perform an error correction code (ECC) check on the data retrieved from the memory device, invoke a recovery operation in response to an ECC error, wherein the recovery operation performs a non-binary, iterative symbol flipping procedure.

In Example 16, the subject matter of Example 15 can optionally include an arrangement in which the recovery operation retrieves soft data associated with the data associated with the read request, the soft data comprises an ECC codeword comprising a plurality of symbols, and the recovery operation comprises evaluating a result of a plurality of parity check operations performed on the data using the plurality of symbols from the ECC codeword.

In Example 17, the subject matter of any one of Examples 15-16 can optionally include logic, at least partially including hardware logic, to select a symbol from the plurality of symbols which results in one or more non-zero parity check operations, determine a first number which represents a number of parity check operations which indicate that the symbol should be decreased, and determine a second number which represents a number of parity check operations which indicate that the symbol should be increased.

In Example 18, the subject matter of any one of Examples 15-17 can optionally include logic, at least partially including hardware logic, to decrease the symbol when the first number is greater than the second number, and assign a low confidence rating to the symbol.

In Example 19, the subject matter of any one of Examples 15-18 can optionally include logic, at least partially including hardware logic, to successively increase the symbol when the first number is greater than the second number, and assign a low confidence rating to the symbol.

In Example 20, the subject matter of any one of Examples 15-19 can optionally include logic, at least partially including hardware logic, to assign a low confidence rating to the symbol when the first number is equal to the second number.

In Example 21, the subject matter of any one of Examples 15-20 can optionally include logic, at least partially including hardware logic, to return a read error to the host device when one or more of the parity check operations includes a 1 after iterative symbol flipping procedure terminates.

In various embodiments of the invention, the operations discussed herein, e.g., with reference to FIGS. 1-10, may be implemented as hardware (e.g., circuitry), software, firmware, microcode, or combinations thereof, which may be provided as a computer program product, e.g., including a tangible (e.g., non-transitory) machine-readable or computer-readable medium having stored thereon instructions (or software procedures) used to program a computer to perform a process discussed herein. Also, the term “logic” may include, by way of example, software, hardware, or combinations of software and hardware. The machine-readable medium may include a storage device such as those discussed herein.

Reference in the specification to “one embodiment” or “an embodiment” means that a particular feature, structure, or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments of the invention, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

1. An apparatus, comprising:
a controller coupled to a memory device and comprising logic, at least partially including hardware logic, to:
in response to a read request received from a host device, retrieve data from the memory device;
perform an error correction code (ECC) check on the data retrieved from the memory device;
invoke a recovery operation in response to an ECC error, wherein the recovery operation performs a non-binary, iterative symbol flipping procedure.

2. The apparatus of claim 1, wherein:
the recovery operation retrieves soft data associated with the data associated with the read request;
the soft data comprises an ECC codeword comprising a plurality of symbols; and
the recovery operation comprises evaluating a result of a plurality of parity check operations performed on the data using the plurality of symbols from the ECC codeword.

3. The apparatus of claim 2, wherein the apparatus further comprises logic, at least partially including hardware logic, to:
select a symbol from the plurality of symbols which results in one or more non-zero parity check operations;
determine a first number which represents a number of parity check operations which indicate that the symbol should be decreased; and
determine a second number which represents a number of parity check operations which indicate that the symbol should be increased.

4. The apparatus of claim 3, wherein the apparatus further comprises logic, at least partially including hardware logic, to:
decrease the symbol when the first number is greater than the second number; and
assign a low confidence rating to the symbol.

5. The apparatus of claim 3, wherein the apparatus further comprises logic, at least partially including hardware logic, to successively:
increase the symbol when the first number is greater than the second number; and
assign a low confidence rating to the symbol.

6. The apparatus of claim 3, wherein the apparatus further comprises logic, at least partially including hardware logic, to:
assign a low confidence rating to the symbol when the first number is equal to the second number.

7. The apparatus of claim 3, wherein the apparatus further comprises logic, at least partially including hardware logic, to:
return a read error to the host device when one or more of the parity check operations includes a 1 after iterative symbol flipping procedure terminates.

8. An electronic device, comprising:
a processor; and
a memory, comprising:
a memory device; and
a controller coupled to the memory device and comprising logic, at least partially including hardware logic, to:
in response to a read request received from a host device, retrieve data from the memory device;
perform an error correction code (ECC) check on the data retrieved from the memory device;
invoke a recovery operation in response to an ECC error, wherein the recovery operation performs a non-binary, iterative symbol flipping procedure.

9. The electronic device of claim 8, wherein:
the recovery operation retrieves soft data associated with the data associated with the read request;
the soft data comprises an ECC codeword comprising a plurality of symbols; and
the recovery operation comprises evaluating a result of a plurality of parity check operations performed on the data using the plurality of symbols from the ECC codeword.

10. The electronic device of claim 9, wherein the controller further comprises logic, at least partially including hardware logic, to:
select a symbol from the plurality of symbols which results in one or more non-zero parity check operations;
determine a first number which represents a number of parity check operations which indicate that the symbol should be decreased; and
determine a second number which represents a number of parity check operations which indicate that the symbol should be increased.

11. The electronic device of claim 10, wherein the controller further comprises logic, at least partially including hardware logic, to:
decrease the symbol when the first number is greater than the second number; and
assign a low confidence rating to the symbol.

12. The electronic device of claim 10, wherein the controller further comprises logic, at least partially including hardware logic, to successively:
increase the symbol when the first number is greater than the second number; and
assign a low confidence rating to the symbol.

13. The electronic device of claim 10, wherein the controller further comprises logic, at least partially including hardware logic, to:
assign a low confidence rating to the symbol when the first number is equal to the second number.

14. The electronic device of claim 10, wherein the controller further comprises logic, at least partially including hardware logic, to:
return a read error to the host device when one or more of the parity check operations includes a 1 after iterative symbol flipping procedure terminates.

15. A controller comprising logic, at least partially including hardware logic, which, when executed, configures the controller to:
in response to a read request received from a host device, retrieve data from the memory device;
perform an error correction code (ECC) check on the data retrieved from the memory device;
invoke a recovery operation in response to an ECC error, wherein the recovery operation performs a non-binary, iterative symbol flipping procedure.

16. The controller of claim 15, wherein:
the recovery operation retrieves soft data associated with the data associated with the read request;
the soft data comprises an ECC codeword comprising a plurality of symbols; and
the recovery operation comprises evaluating a result of a plurality of parity check operations performed on the data using the plurality of symbols from the ECC codeword.

17. The controller of claim 16, wherein the controller further comprises logic, at least partially including hardware logic, to:
select a symbol from the plurality of symbols which results in one or more non-zero parity check operations;
determine a first number which represents a number of parity check operations which indicate that the symbol should be decreased; and
determine a second number which represents a number of parity check operations which indicate that the symbol should be increased.

18. The controller of claim 16, wherein the controller further comprises logic, at least partially including hardware logic, to:
decrease the symbol when the first number is greater than the second number; and
assign a low confidence rating to the symbol.

19. The controller of claim 16, wherein the controller further comprises logic, at least partially including hardware logic, to successively:
increase the symbol when the first number is greater than the second number; and
assign a low confidence rating to the symbol.

20. The controller of claim 16, wherein the controller further comprises logic, at least partially including hardware logic, to:
assign a low confidence rating to the symbol when the first number is equal to the second number.

21. The controller of claim 16, wherein the controller further comprises logic, at least partially including hardware logic, to:
return a read error to the host device when one or more of the parity check operations includes a 1 after iterative symbol flipping procedure terminates.
